(19) United States
(12) Patent Application Publication
(10) Pub. No.: US 2026/0229302 A1
(43) Pub. Date: Aug. 6, 2026

(54) ANALOG MATRIX-MATRIX MULTIPLIER FOR MIXED SIGNAL MATRIX MULTIPLICATIONS

(71) Applicant: INTERNATIONAL BUSINESS MACHINES CORPORATION, ARMONK, NY (US)

(72) Inventors: TAYFUN GOKMEN, Briarcliff Manor, NY (US); Lior Horesh, North Salem, NY (US); Vasileios Kalantzis, Nyack, NY (US); Malte Johannes Rasch, Chappaqua, NY (US)

(21) Appl. No.: 19/044,573

(22) Filed: Feb. 3, 2025

(51) Int. Cl. G11C 27/00; G06G 7/32

(52) U.S. Cl. CPC G11C 27/005; G06G 7/32

(57) ABSTRACT

A compute device architecture includes an array of resistive devices equipped with capacitors holding a charge that stores intermediate results. The array includes signal rows and signal columns that meet at intersections. Signal generators are coupled to the signal rows and signal columns. A read-out circuit is coupled to outputs of the signal rows and signal columns. A controller module is coupled to the signal generators and to the read-out circuit. A set of pulse signals of voltage or resistance are sent through the signal rows and signal columns. Coincidences of pulse signals are detected at intersections of the signal rows and the signal columns. A resultant voltage or resistance is measured at the detected coincidences of pulse signals. A resultant matrix output of the array is updated using the measured resultant voltage or resistance.

### BACKGROUND

### Technical Field

The present disclosure generally relates to computing hardware, and more particularly to an analog matrix-matrix multiplier for mixed signal matrix multiplications.

### Description of the Related Art

GEMMs (General Matrix Multiplications) are a fundamental building block for many operations in neural networks, for example fully-connected layers, recurrent layers such as RNNs, LSTMs or GRUs, and convolutional layers. GEMM is defined as the operation:

C=αAB+βC,

Wherein:
A and B are matrix inputs,
α and β are scalar inputs, and
C as a pre-existing matrix, which is overwritten by the output.

A plain matrix product AB is a GEMM with α equal to one and β equal to zero. For example, in the forward pass of a fully-connected layer, the weight matrix would be argument A, incoming activations would be argument B, and α and β would typically be 1 and 0, respectively. β can be 1 in some cases, for example, if we're combining the addition of a skip-connection with a linear operation.

In computing architectures, GPUs implement GEMMs by partitioning the output matrix into tiles, which are then assigned to thread blocks. Tile size refers to the dimensions of tiles (Mtile×Ntile). Each thread block computes its output tile by stepping through the K dimension in tiles, loading the required values from the A and B matrices, and multiplying and accumulating them into the output.

Using GEMM for convolutional layers treats its input as a two-dimensional image, with a number of channels for each pixel, much like an image with width, height, and depth. The number of channels can be in the hundreds. The convolution operation produces its output by taking a number of ‘kernels’ of weights. and applying them across the image.

Each kernel is another three-dimensional array of numbers, with the depth the same as the input image, but with a much smaller width and height. To produce a result, a kernel is applied to a grid of points across the input image. At each point where it's applied, all of the corresponding input values and weights are multiplied together, and then summed to produce a single output value at that point. The kernel contains a pattern of weights, and when the part of the input image it's looking at has a similar pattern it outputs a high value. When the input doesn't match the pattern, the result is a low number in that position.

### SUMMARY

According to an embodiment of the present disclosure, a compute device architecture is disclosed. The device includes an array of resistive devices equipped with capacitors holding a charge that stores intermediate results. The array includes a plurality of signal rows and a plurality of signal columns that meet at intersections. A first plurality of signal generators are coupled to the plurality of signal rows and are configured to generate a first set of pulse signals stochastically. A second plurality of signal generators are coupled to the plurality of signal columns and are configured to generate the second set of pulse signals stochastically. A read-out circuit is coupled to outputs of the plurality of signal rows and to outputs of the plurality of column rows. A controller module is coupled to the first plurality of signal generators, to the second plurality of signal generators, and to the read-out circuit. The controller module is configured to operate the first plurality of signal generators to send a first set of pulse signals of voltage or resistance through the plurality of signal rows. The second plurality of signal generators send a second set of pulse signals of voltage or resistance through the plurality of signal columns. One or more coincidences of pulse signals are detected at intersections of the plurality of signal rows and the plurality of signal columns. A resultant voltage or resistance is measured at the detected coincidences of pulse signals. A resultant matrix output of the array is updated using the measured resultant voltage or resistance at the detected coincidences of pulse signals.

According to an embodiment of the present disclosure, a computing circuit, is disclosed. The computing circuit includes an array of crossbars, wherein the array includes a plurality of signal rows and a plurality of signal columns. A plurality of resistive processing units (RPUs) are positioned at intersections of the plurality of signal rows and the plurality of signal columns. A controller module is coupled to an input side and to a read-out side of the plurality of signal rows and the plurality of signal columns. The controller module is configured to send a first set of pulse signals representing a first input matrix through the plurality of signal rows. A second set of pulse signals representing a second input matrix are sent through the plurality of signal columns. One or more coincidences of pulse signals are detected at the intersections of the plurality of signal rows and the plurality of signal columns. A resultant signal value is measured at the detected coincidences of pulse signals. A resultant matrix output of the array is updated using the measured resultant signal value at the detected coincidences of pulse signals.

According to an embodiment of the present disclosure, a method of performing a matrix to matrix multiply operation on a computing chip is disclosed. The method includes operating a first plurality of signal generators to send a first set of pulse signals of voltage or resistance through a plurality of signal rows in an array of cross-bar elements. A second plurality of signal generators are operated to send a second set of pulse signals of voltage or resistance through a plurality of signal columns in the array of cross-bar elements. One or more coincidences of pulse signals are detected at intersections of the plurality of signal rows and the plurality of signal columns. A resultant voltage or resistance is measured at the detected coincidences of pulse signals. A resultant matrix output of the array is updated using the measured resultant voltage or resistance at the detected coincidences of pulse signals.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIGS. 1A and 1B are a block diagram of an analog matrix-matrix multiplier circuit for mixed signal matrix multiplications, according to an illustrative embodiment.

FIG. 2 is a schematic view of a matrix-matrix multiplier operation, consistent with an illustrative embodiment.

FIG. 3 is a diagrammatic view of an update cycle operation performed on a cross-bar array of a matrix-matrix multiplier circuit, consistent with an illustrative embodiment.

FIG. 4 is a diagrammatic view of a compute circuit with storage in a matrix array, consistent with an illustrative embodiment.

FIG. 5 is a diagrammatic view of a signal generator circuit for a matrix array, consistent with an illustrative embodiment.

FIGS. 6A and 6B are a diagrammatic view of a cross-bar array and weight update cycle for the array, consistent with an illustrative embodiment.

FIG. 7 is a flowchart of a method of updating a product of a matrix-matrix multiplication, according to an illustrative embodiment.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

### Definitions

Neural network, as used herein, refers to a computational learning system that uses a network of functions to understand and translate a data input of one form into a desired output.

Stochastic, as used herein, refers to a signal generated at random intervals.

Clock cycle, as used herein, refers to a cycle in which stochastically generated pulse signals are generated.

Conductor, as used herein, refers to a metal or other conductive material forming a conductive patch between two conductive elements.

Resultant matrix, as used herein, refers to a matrix of values resulting from the product of two other matrices providing input.

Intersection, as used herein, refers to a point where a conductors crosses over or under another conductor, but not necessarily in contact with each other.

### Overview

The present disclosure generally relates to matrix-matrix multiplication processes. In conventional approaches, for example, a matrix-vector multiplication operation, conductance values need to be pre-programmed as weights for an array performing the operation. Initializing the array to the desired weight values can be costly since the weights occupy hardware space that needs to be set. Pre-programmed weights are generally stationary making the hardware preprogrammed with weights unusable for future neural network applications. In applications using analog computations, the computation is performed according to Ohm's law and Kirchoff's law which can produce non-linear results making the output prone to error.

As will be appreciated, the subject technology disclosed below transforms an initially zero state of a circuit array to another state which is equal to the multiplication of two input matrices. Without weight initialization, the costs associated with programmed weights are eliminated. The hardware using the circuit arrays of the subject matrix-matrix multiplication processes can be re-used for different applications. In addition, the analog computation is performed by coincidence detection and charge accumulation which mitigates the non-linear results associated with using Ohm's law and Kirchoff's law.

According to an embodiment of the present disclosure, a compute device architecture is disclosed. The device includes an array of resistive devices equipped with capacitors holding a charge that stores intermediate results. The array includes a plurality of signal rows and a plurality of signal columns that meet at intersections. A first plurality of signal generators are coupled to the plurality of signal rows and are configured to generate a first set of pulse signals stochastically. A second plurality of signal generators are coupled to the plurality of signal columns and are configured to generate the second set of pulse signals stochastically. A read-out circuit is coupled to outputs of the plurality of signal rows and to outputs of the plurality of column rows. A controller module is coupled to the first plurality of signal generators, to the second plurality of signal generators, and to the read-out circuit. The controller module is configured to operate the first plurality of signal generators to send a first set of pulse signals of voltage or resistance through the plurality of signal rows. The second plurality of signal generators send a second set of pulse signals of voltage or resistance through the plurality of signal columns. One or more coincidences of pulse signals are detected at intersections of the plurality of signal rows and the plurality of signal columns. A resultant voltage or resistance is measured at the detected coincidences of pulse signals. A resultant matrix output of the array is updated using the measured resultant voltage or resistance at the detected coincidences of pulse signals.

According to one embodiment, which can be combined with one or more previous embodiments, the compute device architecture also includes a resistive processing unit (RPU) connected between one of the signal rows to one of the signal columns at one or more of the intersections, wherein the measured resultant voltage or resistance is measured across the RPU. RPUs provide an element that can store and process data locally while being operated in parallel in large scale architecture.

According to one embodiment, which can be combined with one or more previous embodiments, the resistive devices are two-terminal devices or CMOS-based circuits. As may be appreciated, two-terminal devices or CMOS-based circuits may be paired with capacitors to hold a charge that can be used as a measurement for storing intermediate results as the matrices are updated.

According to one embodiment, which can be combined with one or more previous embodiments, the first set of pulse signals represent data of a first matrix of values and the second set of pulse signals represent data of a second matrix of values. The two different matrix values may be compared to generate a third matrix set of values that is used for computation such as neural networks, foundation models, linear algebra solvers, and benchmark standard testing.

According to one embodiment, which can be combined with one or more previous embodiments, the controller is further configured to initialize the array without a weight value. A matrix to matrix multiplication circuit that operates without an initialized weight value avoids the overhead costs associated with preprogramming a circuit. In addition, the hardware used for the matrix to matrix multiplication computations can be re-used for more than one application.

According to one embodiment, which can be combined with one or more previous embodiments, the controller module is further configured to set a supply voltage for the array equal to half of an operating voltage for the array and set an output for the first plurality of signal generators and an output for the second plurality of signal generators to a voltage higher than half of an operating voltage of the array. By setting the supply voltages equal to half of an operating voltage for the array in combination with the compute device architecture disclosed above, the compute device architecture is able to save on power costs while still performing the complex computations associated with a matrix to matrix computation.

According to one embodiment, which can be combined with one or more previous embodiments, the measured resultant voltage or resistance at the detected coincidences of pulse signals are read in parallel. By having an architecture whose measurements can be read in parallel, the compute device architecture processes matrix computation data faster, which can speed up the results for end applications.

According to one embodiment, which can be combined with one or more previous embodiments, the controller is further configured to update an entry into the resultant matrix output of the array based on a charge accumulation on one or more of the plurality of signal rows and the plurality of signal columns.

According to an embodiment of the present disclosure, a computing circuit, is disclosed. The computing circuit includes an array of crossbars, wherein the array includes a plurality of signal rows and a plurality of signal columns. A plurality of resistive processing units (RPUs) are positioned at intersections of the plurality of signal rows and the plurality of signal columns. A controller module is coupled to an input side and to a read-out side of the plurality of signal rows and the plurality of signal columns. The controller module is configured to send a first set of pulse signals representing a first input matrix through the plurality of signal rows. A second set of pulse signals representing a second input matrix are sent through the plurality of signal columns. One or more coincidences of pulse signals are detected at the intersections of the plurality of signal rows and the plurality of signal columns. A resultant signal value is measured at the detected coincidences of pulse signals. A resultant matrix output of the array is updated using the measured resultant signal value at the detected coincidences of pulse signals.

According to one embodiment, which can be combined with one or more previous embodiments, the controller is further configured to generate the first set of pulse signals and the second set of pulse signals stochastically. By using stochastic signaling, weight initialization becomes unnecessary which reduces some costs associated with programming a circuit with fixed values.

According to one embodiment, which can be combined with one or more previous embodiments, the controller is further configured to start a transmission of the first set of pulse signals asynchronously from a transmission of the second set of pulse signals. Asynchronous signal transmissions frees the circuit from overhead associated with controlling a clock in the circuit to ensure synchronized signaling.

According to one embodiment, which can be combined with one or more previous embodiments, the controller module is further configured to set a supply voltage for the array equal to half of an operating voltage for the array and set an output for the first signal generator and an output for the second signal generator to a voltage higher than half of an operating voltage of the array. By setting the supply voltages equal to half of an operating voltage for the array in combination with the compute device architecture disclosed above, the compute device architecture is able to save on power costs while still performing the complex computations associated with a matrix to matrix computation.

According to one embodiment, which can be combined with one or more previous embodiments, the measured resultant signal at the detected coincidences of pulse signals are read in parallel. By having an architecture whose measurements can be read in parallel, the compute device architecture processes matrix computation data faster, which can speed up the results for end applications.

According to one embodiment, which can be combined with one or more previous embodiments, the controller is further configured to update an entry into the resultant matrix output of the array based on a charge accumulation on one or more of the plurality of signal rows and the plurality of signal columns.

According to an embodiment of the present disclosure, a method of performing a matrix to matrix multiply operation on a computing chip is disclosed. The method includes operating a first plurality of signal generators to send a first set of pulse signals of voltage or resistance through a plurality of signal rows in an array of cross-bar elements. A second plurality of signal generators are operated to send a second set of pulse signals of voltage or resistance through a plurality of signal columns in the array of cross-bar elements. One or more coincidences of pulse signals are detected at intersections of the plurality of signal rows and the plurality of signal columns. A resultant voltage or resistance is measured at the detected coincidences of pulse signals. A resultant matrix output of the array is updated using the measured resultant voltage or resistance at the detected coincidences of pulse signals.

According to one embodiment, which can be combined with one or more previous embodiments, the method includes initializing the array without a weight value. A matrix to matrix multiplication circuit that operates without an initialized weight value avoids the overhead costs associated with preprogramming a circuit, In addition, the hardware used for the matrix to matrix multiplication computations can be re-used for more than one application.

According to one embodiment, which can be combined with one or more previous embodiments, the method includes generating the first set of pulse signals stochastically and generating the second set of pulse signals stochastically. By using stochastic signaling, weight initialization becomes unnecessary which reduces some costs associated with programming a circuit with fixed values.

According to one embodiment, which can be combined with one or more previous embodiments, the method includes reading the measured resultant voltage or resistance at the detected coincidences of pulse signals in parallel. By having an architecture whose measurements can be read in parallel, the compute device architecture processes matrix computation data faster, which can speed up the results for end applications.

According to one embodiment, which can be combined with one or more previous embodiments, the method includes updating an entry into the resultant matrix output of the array based on a charge accumulation on one or more of the plurality of signal rows and the plurality of signal columns.

### Example Architecture

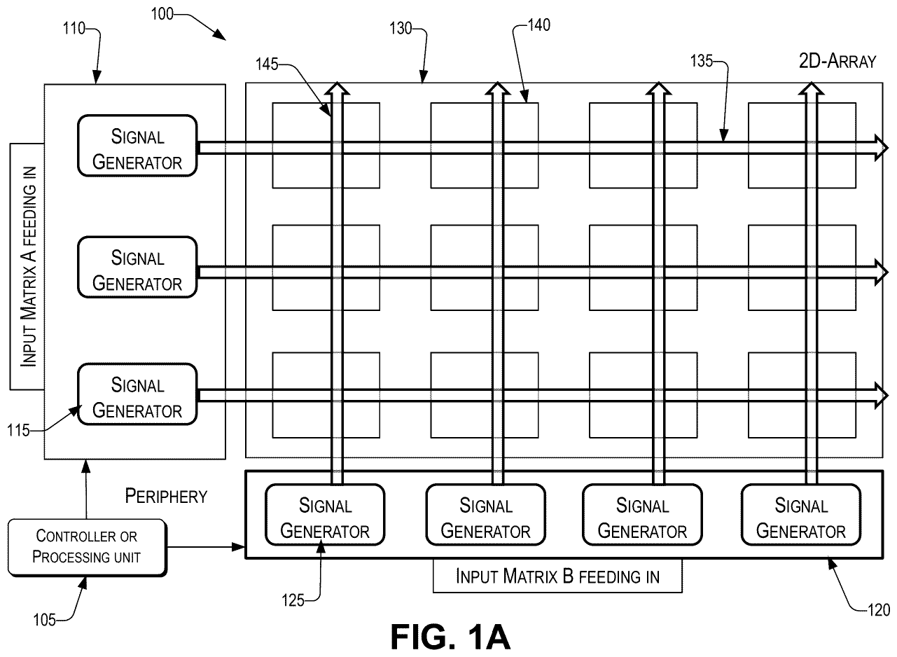

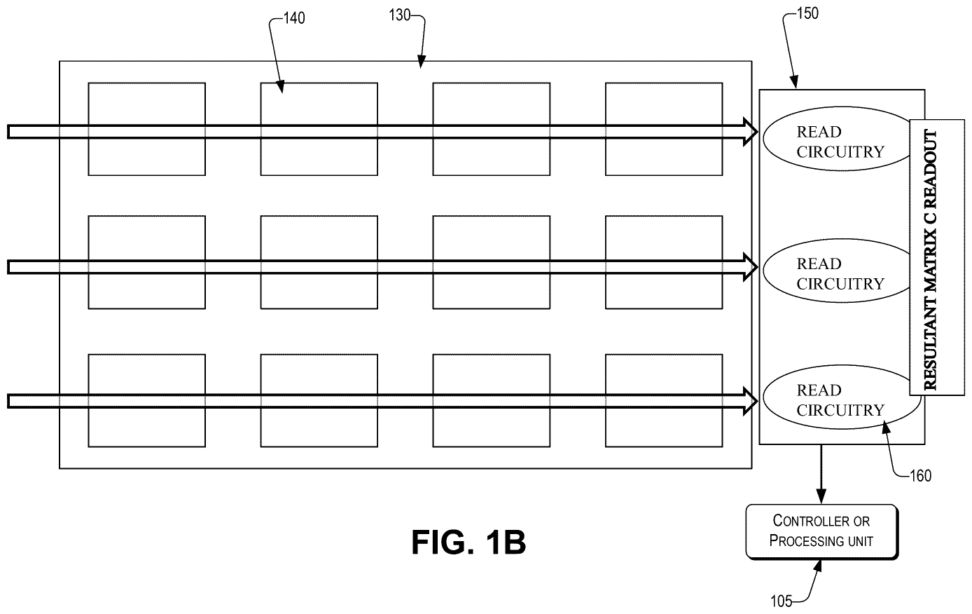

According to an embodiment of the present disclosure, an analog matrix-matrix multiplier circuit 100 for mixed signal matrix multiplications is disclosed. FIGS. 1A and 1B show an architecture of the analog matrix-matrix multiplier circuit 100. The analog matrix-matrix multiplier circuit 100 is configured to generate matrix-matrix multiplication operations using two matrices (input matrix A represented by box 110 and input matrix B represented by box 120) providing signal inputs into a cross-bar array 130. In some embodiments, the analog matrix-matrix multiplier circuit 100 includes a controller module or processing unit 105 coupled to the input and output side of the circuit.

On the input side, the analog matrix-matrix multiplier circuit 100 may include a signal generator 115 coupled to each cross-bar row associated with the input matrix A 110 and a signal generator 125 coupled to each cross-bar column associated with input matrix B 120. The signal generator 115 may send stochastic pulses 135 along the cross-bar rows associated with the input matrix A 110. The signal generator 125 may send stochastic pulses 145 along the cross-bar columns associated with the input matrix B 120. Compute circuits 140 may be positioned at the intersections of cross-bars in the array 130. The compute circuits 140 may comprise a CMOS based resistive processing unit (RPU).

On the output side, the analog matrix-matrix multiplier circuit 100 also includes a resultant output matrix 150 that receives resultant data measured by the compute circuits 140. The resultant data is registered by read circuits 160 coupled to an output point of every cross-bar row and cross-bar column. The physical elements of the analog matrix-matrix multiplier circuit 100 are disclosed more fully below.

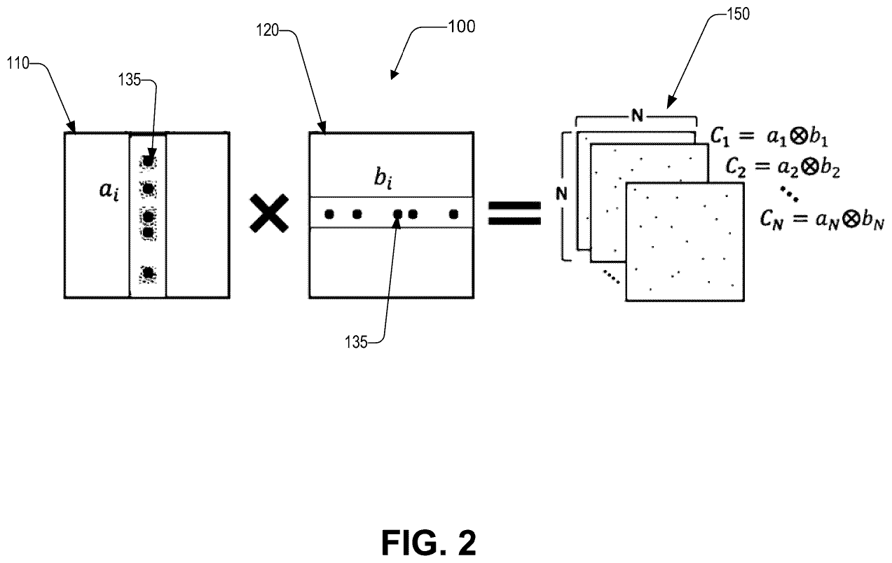

FIG. 2 shows a conceptual representation of the matrix-matrix multiplication. In general, as stochastic pulses 135 and 145 are sent through the array 130, when a pulse coincidence occurs at an intersection of cross-bars, the compute circuit 140 registers the coincidence, for example, by measuring a resultant voltage or resistance at the detected coincidences of pulse signals. The output matrix 150 is updated with the coincidence data using the measured resultant voltage or resistance at the detected coincidences of pulse signals.

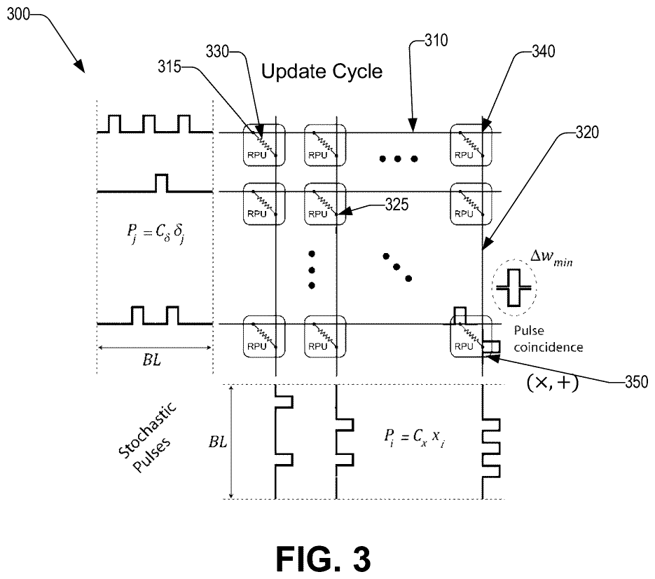

FIG. 3 shows an example of a circuit array 300 during an update cycle operation for matrix-matrix multiplication consistent with embodiments of the subject technology. The circuit array 300 includes conductors 310 running horizontally and conductors 320 running vertically. While the conductors 310 and 320 appear to cross over each other, the conductors 310 and 320 do not connect directly (i.e., do not make direct physical contact) at intersection points 340. The conductors 310 and 320 may be disposed on different levels. Connection between the conductors 310 and 320 is made through RPUs (sometimes also referred to as “resistive cross-point devices”) 330 located at each intersection point 340. One end of an RPU connection 315 is connected to the conductor 310. The other end of the RPU connection 325 is connected to the conductor 320. The RPUs 330 provide a highly parallel and scalable architecture composed of resistive devices for back-propagating neural networks. The RPUs 330 may include a memory storage element, (e.g., programmable memristor, resistive random access memory (ReRAM or RRAM), etc.).

The RPUs 330 provide a scalable architecture composed of resistive devices that may include phase change, transition metal oxide, conductance change or resistive switching technology to alter input signals and to store data information. The RPUs 330 may be configured to implement an independent component analysis (ICA) Infomax algorithm. ICA Infomax is an optimization for artificial neural networks and other information processing systems. It prescribes that a function that maps a set of input values to a set of output values should be chosen or learned to improve (e.g., maximize) average Shannon mutual information between the inputs and outputs, subject to a set of specified constraints and/or noise processes. Infomax algorithms perform the optimization process. Independent component analysis (ICA) finds independent signals by increasing (e.g., maximizing) entropy.

In the subject application, RPUs 330 are used for matrix multiplication. For forward matrix multiplication, voltages may be supplied on conductors 310 in rows, and currents are read from conductors 320 in columns. While in some applications, conductance values σ may be stored as weights, (for example, conductance values in the array would include σ11, σ12, σ13, σ21, σ22, σ23, σ31, σ32, σ33, σ41, σ42, σ43, etc.), methods of the subject technology can be performed without the need of predefined weight values. For backward matrix multiplication, the voltages are supplied on the columns for conductors 320 and current is read from the rows of conductors 310.

Signal updates are achieved when stochastic voltage pulses from a conductor 310 arrive coincidentally at RPU connection 315 with a stochastic voltage pulse arriving at RPU connection 325 on a conductor 320. See for example, the pulse coincidence that occurs at RPU 350. In one example, I4=V1σ41+V2σ42+V3σ43 as coincident occurrences of signals are registered. The conductance values may be updated all in parallel in the resultant matrix. It should be understood that the function and position of rows and columns are interchangeable, and the columns and rows may be switched depending on the application.

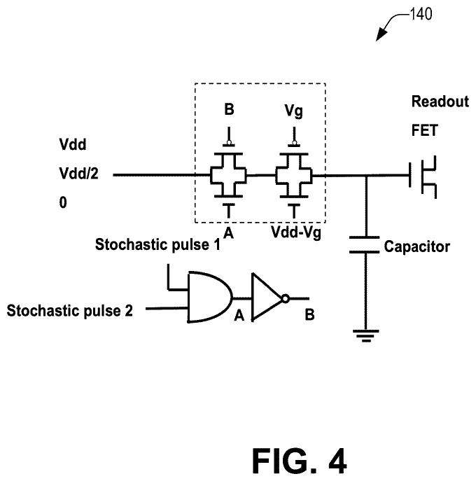

FIG. 4 shows an example of a compute circuit 140 with storage that is part of the analog matrix-matrix multiplier circuit 100 of FIGS. 1A and 1B. The compute circuit 140 shown is a CMOS based RPU.

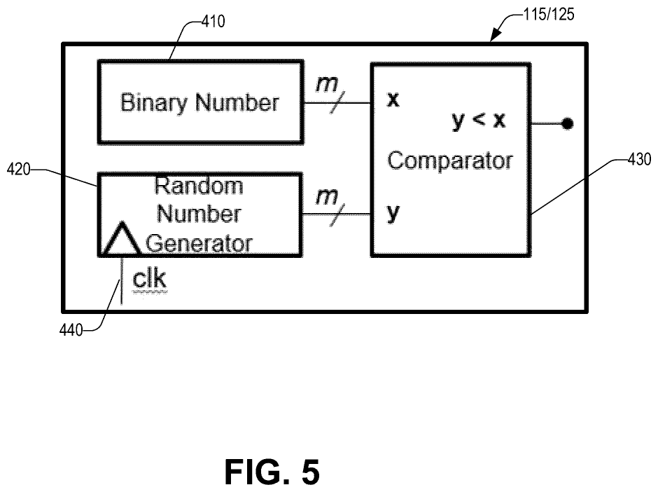

FIG. 5 shows an example of a signal generator circuit (115/125) for the analog matrix-matrix multiplier circuit 100 of FIGS. 1A and 1B. The signal generator circuit (115/125) includes a binary number generator 410, a random number generator 420, a comparator 430, and a clock signal 440. The signal generator circuit (115/125) is configured for binary to stochastic conversion of input signals. An m-bit random binary number in each clock cycle is generated by the random number generator 420. The m-bit random binary number is compared to an m-bit input binary number generated by the binary number generator 410. The comparator 430 produces a 1 if the random number is less than the binary number and a 0 otherwise. The output from the signal generator circuit (115/125) results in stochastic pulses 135 and 145 (FIGS. 1A and 1B) that are sent along the conductors 310 and 320 of FIG. 3.

In some embodiments, the controller module or processing unit 105 (FIGS. 1A and 1B) may set a supply voltage for the array equal to half of an operating voltage for the array. In addition, an output for the signal generator circuits (115/125) may be set to a voltage higher than half of the operating voltage.

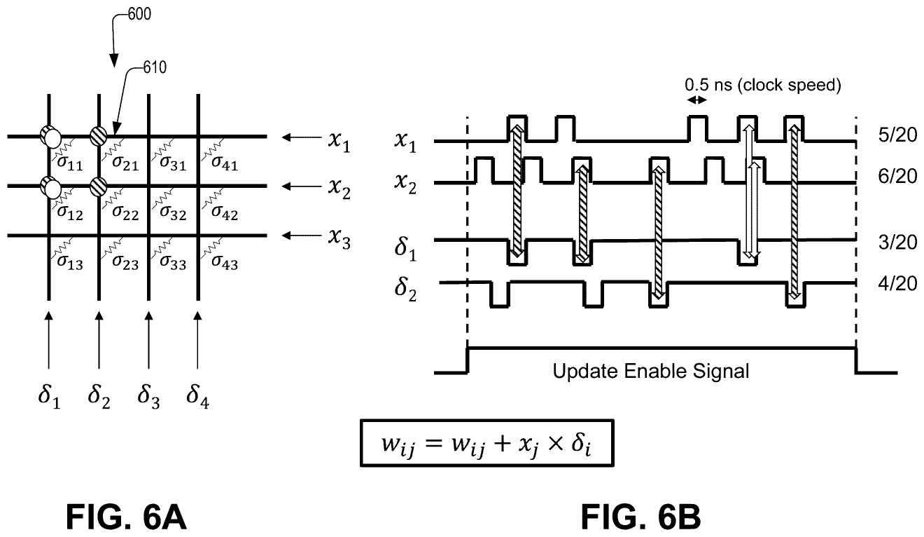

FIG. 6 shows a circuit array 600 with signal pulses on rows and columns similar to the circuit array 300. FIG. 6B illustrates how stochastic signal pulses on the array 600 may be registered when pulses from respective rows and columns are coincident at an RPU 610. Registered coincident pulses may be used to update weight values in a resultant matrix. Stochastic bit streams (generated signals) are used to encode the values. The signals from rows and columns may be asynchronous. Overlapping signals (FIG. 6B) represent coincident occurrences of row and column bit streams, which will be used update the weight values in the resultant matrix slightly. The number of overlapping signals are stochastic but on average proportional to xⱼ×δᵢ. The whole resulting matrix may be updated all in parallel independent of its size.

### Methodology

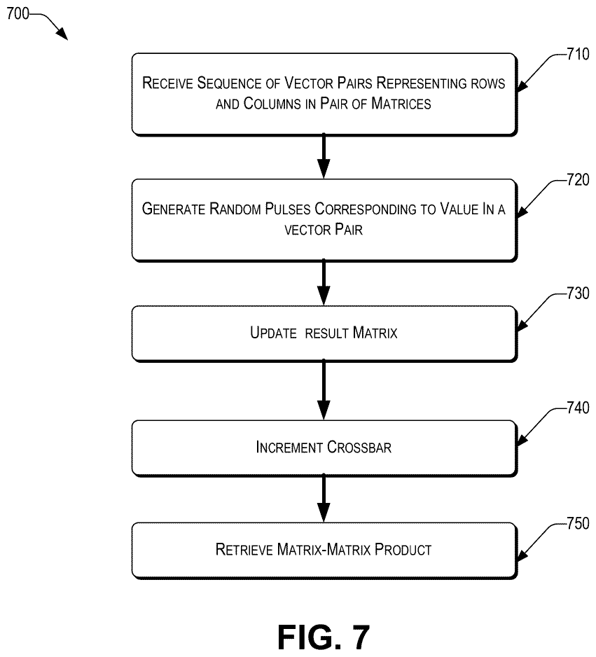

Referring now to FIG. 7, a method 700 of performing a matrix to matrix multiply operation on a computing chip is shown. The matrix to matrix to multiply operation may be performed on a circuit array including cross-resistive devices. In some embodiments, a controller or processing unit performing the matrix to matrix to multiply operation may initialize the values of the circuit array without a weight value.

In block 710, a controller or processing unit may receive a sequence of vector pairs representing rows and columns in a pair of matrices. The matrices may represent input signals generated from a pair of signal generation sources. In block 720, random pulses may be generated corresponding to value in a vector pair. The random pulses may be generated by operating a first plurality of signal generators to send a first set of pulse signals of voltage or resistance through a plurality of signal rows in an array of cross-bar elements of a circuit array. In addition, a second plurality of signal generators may be operated to send a second set of pulse signals of voltage or resistance through a plurality of signal columns in the array of cross-bar elements. In some embodiments, the first and second set of pulse signals may be generated stochastically. One or more coincidences of pulse signals may be detected at intersections of the plurality of signal rows and the plurality of signal columns. The resultant voltage or resistance at the detected coincidences of pulse signals may be measured. In some embodiments, the measured resultant voltage or resistance at the detected coincidences of pulse signals may be read in parallel. In block 730, a resultant matrix output of the array may be updated using the measured resultant voltage or resistance at the detected coincidences of pulse signals. The entry into the resultant matrix output of the array may be updated based on a charge accumulation on one or more of the signal rows and the signal columns. For example, if the pulses coincide on the up side, the event may be reflected as an increment on the crossbar and this is done by increasing (accumulating) the charge value. In block 740, the values for each cross-bar may be incremented after the resultant matrix is updated. In block 750, the controller or processing unit may retrieve the matrix by matric product value results from the updated resultant matrix.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

Aspects of the present disclosure are described herein with reference to call flow illustrations and/or block diagrams of a method, apparatus (systems), and computer program products according to embodiments of the present disclosure. It will be understood that each step of the flowchart illustrations and/or block diagrams, and combinations of blocks in the call flow illustrations and/or block diagrams, can be implemented by computer readable program instructions.

These computer readable program instructions may be provided to a processor of a computer, special purpose computer, or other programmable data processing apparatus to produce a machine, such that the instructions, which execute via the processor of the computer or other programmable data processing apparatus, create means for implementing the functions/acts specified in the call flow process and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the call flow and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the call flow process and/or block diagram block or blocks.

The flowchart and block diagrams in the Figures illustrate the architecture, functionality, and operation of possible implementations of systems, methods, and computer program products according to various embodiments of the present disclosure. In this regard, each block in the call flow process or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or call flow illustration, and combinations of blocks in the block diagrams and/or call flow illustration, can be implemented by special purpose hardware-based systems that perform the specified functions or acts or carry out combinations of special purpose hardware and computer instructions.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A compute device architecture, comprising:
an array of resistive devices equipped with capacitors holding a charge that stores intermediate results, wherein the array includes a plurality of signal rows and a plurality of signal columns that meet at intersections;
a first plurality of signal generators coupled to the plurality of signal rows, configured to generate a first set of pulse signals stochastically;
a second plurality of signal generators coupled to the plurality of signal columns, configured to generate a second set of pulse signals stochastically;
a read-out circuit coupled to outputs of the plurality of signal rows and to outputs of the plurality of signal columns; and
a controller module coupled to the first plurality of signal generators, to the second plurality of signal generators, and to the read-out circuit, wherein the controller module is configured to:
operate the first plurality of signal generators to send the first set of pulse signals through the plurality of signal rows;
operate the second plurality of signal generators to send a second set of pulse signals through the plurality of signal columns;
detect one or more coincidences of pulse signals at intersections of the plurality of signal rows and the plurality of signal columns;
measure a resultant voltage or resistance at each of the one or more coincidences of pulse signals; and
update a resultant matrix output of the array using the measured resultant voltage or resistance at the detected one or more coincidences of pulse signals.

2. The compute device architecture of claim 1, further comprising a resistive processing unit (RPU) connected between one of the signal rows to one of the signal columns at one or more of the intersections, wherein the measured resultant voltage or resistance is measured across the RPU.

3. The compute device architecture of claim 1, wherein the resistive devices are two-terminal devices or CMOS-based circuits.

4. The compute device architecture of claim 1, wherein:
the first set of pulse signals represent data of a first matrix of values; and
the second set of pulse signals represent data of a second matrix of values.

5. The compute device architecture of claim 1, wherein the controller module is further configured to initialize the array without a weight value.

6. The compute device architecture of claim 1, wherein controller module is further configured to:
set a supply voltage for the array equal to half of an operating voltage for the array; and
set an output for the first plurality of signal generators and an output for the second plurality of signal generators to a voltage higher than half of an operating voltage of the array.

7. The compute device architecture of claim 1, wherein the measured resultant voltage or resistance at each of the one or more coincidences of pulse signals are read in parallel.

8. The compute device architecture of claim 1, wherein the controller module is further configured to update an entry into the resultant matrix output of the array based on a charge accumulation on one or more of the plurality of signal rows and the plurality of signal columns.

9. A computing circuit, comprising:
an array of crossbars, wherein the array includes a plurality of signal rows and a plurality of signal columns;
a plurality of resistive processing units (RPUs) positioned at intersections of the plurality of signal rows and the plurality of signal columns; and
a controller module coupled to an input side and to a read-out side of the plurality of signal rows and the plurality of signal columns, wherein the controller module is configured to:
initialize the array without a weight value;
send a first set of pulse signals representing a first input matrix through the plurality of signal rows;
send a second set of pulse signals representing a second input matrix through the plurality of signal columns;
detect one or more coincidences of pulse signals at the intersections of the plurality of signal rows and the plurality of signal columns;
measure a resultant signal value at e each of the one or more coincidences of pulse signals; and
update a resultant matrix output of the array using the measured resultant signal value at the detected coincidences of pulse signals.

10. The computing circuit of claim 9, wherein the controller module is further configured to generate the first set of pulse signals and the second set of pulse signals stochastically.

11. The computing circuit of claim 9, wherein the controller module is further configured to start a transmission of the first set of pulse signals asynchronously from a transmission of the second set of pulse signals.

12. The computing circuit of claim 9, wherein controller module is further configured to:
set a supply voltage for the array equal to half of an operating voltage for the array; and
set an output for the first set of pulse signals and an output for the second set of pulse signals to a voltage higher than half of an operating voltage of the array.

13. The computing circuit of claim 9, wherein the measured resultant signal at each of the one or more coincidences of pulse signals are read in parallel.

14. The computing circuit of claim 9, wherein the controller module is further configured to update an entry into the resultant matrix output of the array based on a charge accumulation on one or more of the plurality of signal rows and the plurality of signal columns.

15. A method of performing a matrix to matrix multiply operation on a computing chip, comprises:
operating a first plurality of signal generators to generate a first set of pulse signals stochastically;
sending the first set of pulse signals through a plurality of signal rows in an array of cross-bar elements;
operating a second plurality of signal generators to generate a second set of pulse signals stochastically;
sending the second set of pulse signals through a plurality of signal columns in an array of cross-bar elements;
detecting one or more coincidences of pulse signals at intersections of the plurality of signal rows and the plurality of signal columns;
measuring a resultant voltage or resistance at each of the one or more coincidences of pulse signals; and
updating a resultant matrix output of the array using the measured resultant voltage or resistance at each of the one or more coincidences of pulse signals.

16. The method of claim 15, further comprising initializing the array without a weight value.

17. The method of claim 15, further comprising reading the measured resultant voltage or resistance at each of the one or more coincidences of pulse signals, in parallel.

18. The method of claim 15, further comprising updating an entry into the resultant matrix output of the array based on a charge accumulation on one or more of the plurality of signal rows and the plurality of signal columns.

19. The method of claim 15, further comprising reading the measured resultant voltage or resistance across one or more resistive processing units connected between the plurality of signal rows and the plurality of signal columns.

20. The method of claim 15, further comprising:
setting a supply voltage for the array equal to half of an operating voltage for the array; and
setting an output for the first plurality of signal generators and an output for the second plurality of signal generators to a voltage higher than half of an operating voltage of the array.
